(19) United States
(12) Patent Application Publication
(10) Pub. No.: US 2024/0389429 A1
(43) Pub. Date: Nov. 21, 2024

(54) DISPLAY MODULE AND DISPLAY DEVICE

(71) Applicants: BOE TECHNOLOGY GROUP CO., LTD., Beijing (CN); CHENGDU BOE OPTOELECTRONICS TECHNOLOGY CO., LTD., Sichuan (CN)

(72) Inventors: Bowen XIAO, Beijing (CN); Xuan TAO, Beijing (CN); Binfeng FENG, Beijing (CN); Fei LI, Beijing (CN); Feifan LI, Beijing (CN); Zhicai XU, Beijing (CN); Shaoning LIU, Beijing (CN); Shangnan JIN, Beijing (CN); Qi HUANG, Beijing (CN); Yihao ZHAO, Beijing (CN); Xingxing LI, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/254,975

(22) PCT Filed: Apr. 29, 2022
(86) PCT No.: PCT/CN2022/090546

§ 371 Date: May 30, 2023

(51) Int. Cl. H10K 59/80; H10K 59/90

(52) U.S. Cl. CPC H10K 59/80; H10K 59/8794; H10K 59/90

(57) ABSTRACT

A display module includes a display panel and a support backplane located on a side of the display panel where a non-display surface of the display panel is located. The support backplane has a first region and a second region disposed on a periphery of the first region. At least a portion of a portion, located in the second region, of the support backplane is etched away to form at least one groove.

### CROSS-REFERENCE TO RELATED APPLICATION

This application is a national phase entry under 35 USC 371 of International Patent Application No. PCT/CN 2022/090546 filed on Apr. 29, 2022, which is incorporated herein by reference in its entirety.

### TECHNICAL FIELD

The present disclosure relates to the field of display technologies, and in particular, to a display module and a display device.

### BACKGROUND

As active light-emitting display devices, organic light-emitting diode (OLED) display devices have advantages of self-luminescence, wide viewing angle, high contrast, low power consumption, wide color gamut, light weight and thinness, and shapeability. With the development of display technologies, the technical application of OLED's flexible features has become one of the current development trends.

### SUMMARY

In an aspect, a display module is provided. The display module includes a display panel and a support backplane disposed on a side of the display panel where a non-display surface of the display panel is located. The support backplane has a first region and a second region disposed on a periphery of the first region. At least a portion of a portion, located in the second region, of the support backplane is etched away to form at least one groove.

In some embodiments, the at least one groove includes a plurality of grooves. The plurality of grooves are loop-shaped, and are sequentially spaced apart from inside to outside.

In some embodiments, depths of the plurality of grooves in a first direction are equal, and the first direction is a direction perpendicular to a plane where the support backplane is located; or in a direction from the inside to the outside with the first region as a center, the depths of the plurality of grooves in the first direction are sequentially reduced.

In some embodiments, a spacing distance between two adjacent grooves in the plurality of grooves is equal, and a distance between a groove closest to the first region and the first region is greater than or equal to the spacing distance between the two adjacent grooves.

In some embodiments, a ratio of a depth, in the first direction, of each of the plurality of grooves to a thickness, in the first direction, of the support backplane is greater than or equal to 0.5 and is less than 1.

In some embodiments, the at least one groove includes a single groove. The groove is loop-shaped, and the groove and the first region are non-spaced apart.

In some embodiments, in a sectional view of the support backplane taken along a straight line passing through a center of the first region, a depth, in the first direction, of the groove at a position away from the first region is less than a depth, in the first direction, of the groove at a position close to the first region.

In some embodiments, in the sectional view, the groove has a stepped or triangular shape.

In some embodiments, a ratio of a depth of the groove in the first direction to a thickness of the support backplane in the first direction is equal to or less than 0.5.

In some embodiments, the first region is in a shape of a circle, and a groove in the at least one groove is in a shape of a circular loop.

In some embodiments, a ratio of a peripheral dimension of the second region to a peripheral dimension of the first region is 1.5.

In some embodiments, a through hole is disposed in the first region, and a border of the through hole coincides with an inner border of the second region; or an electroplating structure is disposed in the first region, and is located on a side of the support backplane away from the display panel. A border of the electroplating structure is spaced apart from a border of the first region.

In some embodiments, the display module further includes a first adhesive layer, a heat dissipation film, a polarizer, a second adhesive layer and a cover plate. The first adhesive layer is disposed on a side of the support backplane proximate to the display panel. The heat dissipation film is disposed on a side of the first adhesive layer proximate to the display panel. The polarizer is disposed on a side of the display panel where a display surface of the display panel is located. The second adhesive layer is disposed on a side of the polarizer away from the display panel. The cover plate is disposed on a side of the second adhesive layer away from the display panel.

In another aspect, a display device is provided. The display device includes the display module in the above aspect and a driving chip. The driving chip is electrically connected to the display panel in the display module.

In some embodiments, the display panel includes a first region, a second region and a bending region located between the first region and the second region. The second region of the display panel is bent to a side of the support backplane away from the display panel. An adhesive tape is disposed between the support backplane and the second region of the display panel, and the support backplane is fixedly connected to the second region of the display panel through the adhesive tape. The second region of the display panel is electrically connected to the driving chip.

In some embodiments, the display device further includes a printed circuit board disposed on a side of the support backplane away from the display panel. The printed circuit board is electrically connected to the display panel through a chip on film, and the driving chip is disposed on the printed circuit board. The support backplane is connected to the printed circuit board through a buffer connection member.

In some embodiments, the buffer connection member includes a connection pillar and a buffer bracket disposed on a periphery of the connection pillar, and the buffer bracket has a hollow structure.

In some embodiments, an orthographic projection of the buffer connection member on the support backplane is in a shape of a gear. An angle between two adjacent teeth of the gear is greater than 15°, and a wall thickness of each tooth is greater than or equal to 0.02 mm.

In some embodiments, a difference between a tip diameter of the gear and a root diameter of the gear is greater than or equal to 0.2 mm, and the root diameter of the gear is greater than or equal to 3 mm.

In some embodiments, the buffer connection member is made of metal. The connection pillar is a metal pillar, and the buffer bracket is formed by folding a reinforcing steel plate.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings without any creative effort.

FIG. 1A is a diagram showing a stacked structure of a backlight module, in accordance with the present disclosure;

FIG. 1B is a diagram showing a stacked structure of another display module, in accordance with the present disclosure;

FIG. 2A is a state diagram of a display module in which major film pressing marks are generated, in accordance with the present disclosure;

FIG. 2B is another state diagram of a display module in which major film pressing marks are generated, in accordance with the present disclosure;

FIG. 3A is a diagram showing a planar structure of a support backplane in a display module, in accordance with some embodiments of the present disclosure;

FIG. 3B is a diagram showing another planar structure of a support backplane in a display module, in accordance with some embodiments of the present disclosure;

FIG. 3C is a sectional view of the support backplane taken along the section line AA in FIG. 3A;

FIG. 3D is another sectional view of the support backplane taken along the section line AA in FIG. 3A;

FIG. 3E is yet another sectional view of the support backplane taken along the sectional line BB in FIG. 3B;

FIG. 3F is yet another sectional view of the support backplane taken along the sectional line BB in FIG. 3B;

FIG. 3G is a state diagram of a display module with minor film pressing marks obtained according to FIG. 3F;

FIG. 4A is a diagram showing yet another planar structure of a support backplane in a display module, in accordance with some embodiments of the present disclosure;

FIG. 4B is a diagram showing yet another planar structure of a support backplane in a display module, in accordance with some embodiments of the present disclosure;

FIG. 4C is a sectional view of the support backplane taken along the section line CC in FIG. 4A;

FIG. 4D is another sectional view of the support backplane taken along the section line CC in FIG. 4A;

FIG. 4E is yet another sectional view of the support backplane taken along the section line DD in FIG. 4B;

FIG. 4F is yet another sectional view of the support backplane taken along the section line DD in FIG. 4B;

FIG. 5A is a structural diagram of a display device, in accordance with some embodiments of the present disclosure;

FIG. 5B is a structural diagram of another display device, in accordance with some embodiments of the present disclosure;

FIG. 6 is a structural diagram of yet another display device, in accordance with some embodiments of the present disclosure;

FIG. 7 is a structural diagram of yet another display device, in accordance with some embodiments of the present disclosure;

FIG. 8 is a top view of buffer connection members in FIG. 7;

FIG. 9 is a side view of a buffer connection member in FIG. 7;

FIG. 10 is a partial enlarged view of FIG. 8; and

FIG. 11 is a partial enlarged view of FIG. 9.

### DETAILED DESCRIPTION

In order to make the above objectives, features and advantages of the present disclosure more comprehensible, technical solutions in the embodiments of the present disclosure will be described clearly and completely below with reference to the accompanying drawings in the embodiments of the present disclosure. Obviously, the described embodiments are merely some but not all embodiments of the present application. All other embodiments obtained by a person of ordinary skill in the art without any creative effort based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “an example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are only used for descriptive purposes, and are not to be construed as indicating or implying relative importance or implicitly indicating the number of indicated technical features. Thus, a feature defined with “first” or “second” may explicitly or implicitly include one or more of the features. In the description of the embodiments of the present disclosure, the term “a plurality of/the plurality of” means two or more unless otherwise specified.

In the description of some embodiments, the terms such as “coupled” and “connected” and extensions thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the contents herein.

The phrase “A and/or B” includes following three combinations: only A, only B, and a combination of A and B.

The use of the phrase “applicable to” or “configured to” herein means an open and inclusive expression, which does not exclude devices that are applicable to or configured to perform additional tasks or steps.

In addition, as used herein, the term such as “parallel,” “perpendicular” or “equal” includes a stated condition and condition(s) similar to the stated condition. The similar condition(s) are within an acceptable range of deviation as determined by a person of ordinary skill in the art, considering measurement in question and errors associated with measurement of a particular quantity (i.e., limitations of a measurement system). For example, the term “parallel” includes “absolutely parallel” and “approximately parallel”, and for the phrase “approximately parallel”, an acceptable range of deviation may be, for example, within 5°. The term “perpendicular” includes “absolutely perpendicular” and “approximately perpendicular”, and for the phrase “approximately perpendicular”, an acceptable range of deviation may also be, for example, within 5°. The term “equal” includes “absolutely equal” and “approximately equal”, and for the phrase “approximately equal”, an acceptable range of deviation may be that, for example, a difference between two that are equal to each other is less than or equal to 5% of any one of the two.

It will be understood that when a layer or element is described as being on another layer or substrate, the layer or element may be directly on the another layer or substrate, or intermediate layer(s) may exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing techniques and/or tolerances may be envisaged. Therefore, the exemplary embodiments should not be construed to be limited to the shapes of regions shown herein, but to include deviations in shape due to, for example, manufacturing. For example, an etched region shown in a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

At present, with the development of display technologies, in addition to continuing to shine in the field of cell phones, a flexible characteristic of an OLED flexible module has also begun a rapid development in the field of vehicles. Under-screen opening and under-screen camera techniques for OLED products have been gradually applied to the flexible folding, sliding and rolling, or automotive display. However, due to lightness and thinness of the OLED flexible module itself, there is a risk of film pressing marks during assembly of the module. For example, an uneven phenomenon occurs in a region of the OLED flexible module corresponding to an under-screen opening, which affects the quality of the OLED flexible module.

Based on this, some embodiments of the present disclosure provide a display module and a display device. A buffer structure is provided on a periphery of a through hole, i.e., a portion of the periphery of the through hole is etched away, so that deformation caused by stress is reduced, so as to reduce major film pressing marks, thereby providing more perfect visual effect for consumers.

The display module and the display device provided in the present disclosure will be described below.

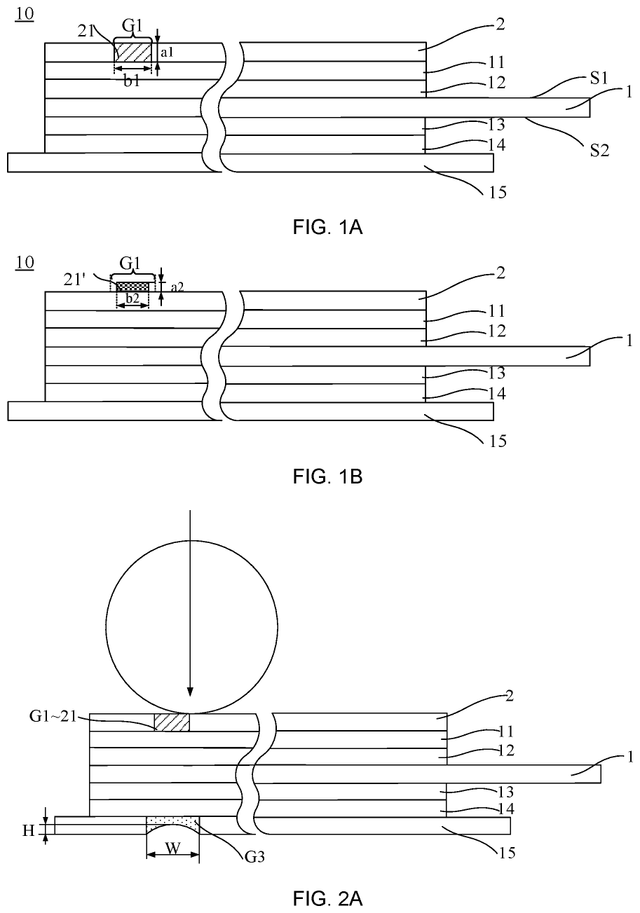

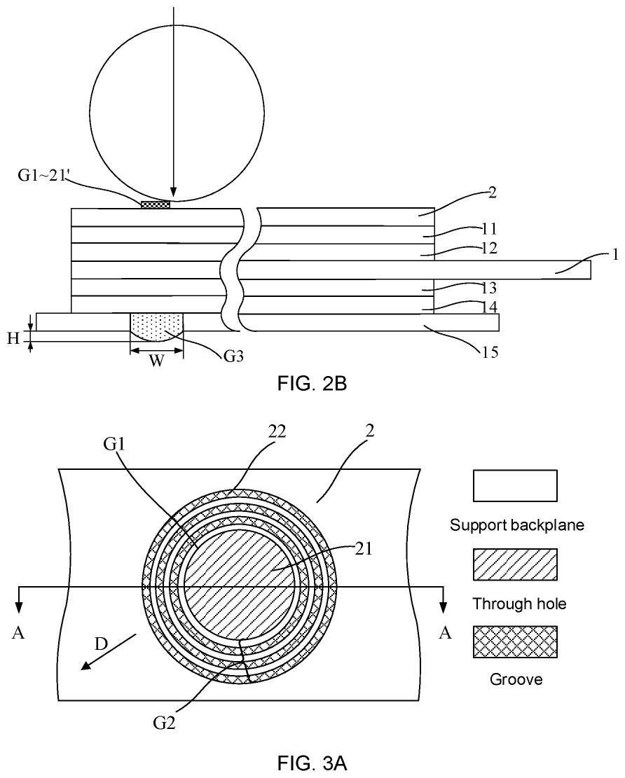

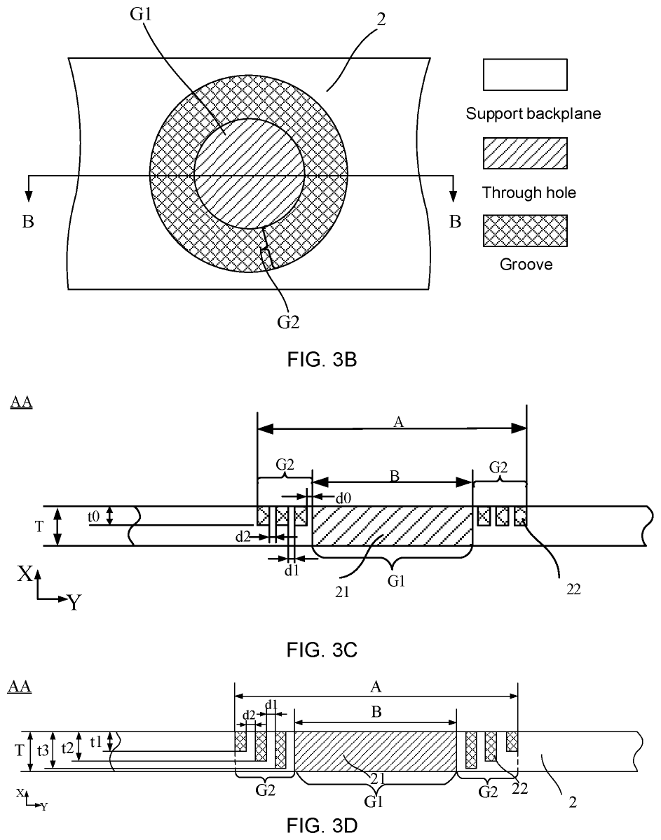

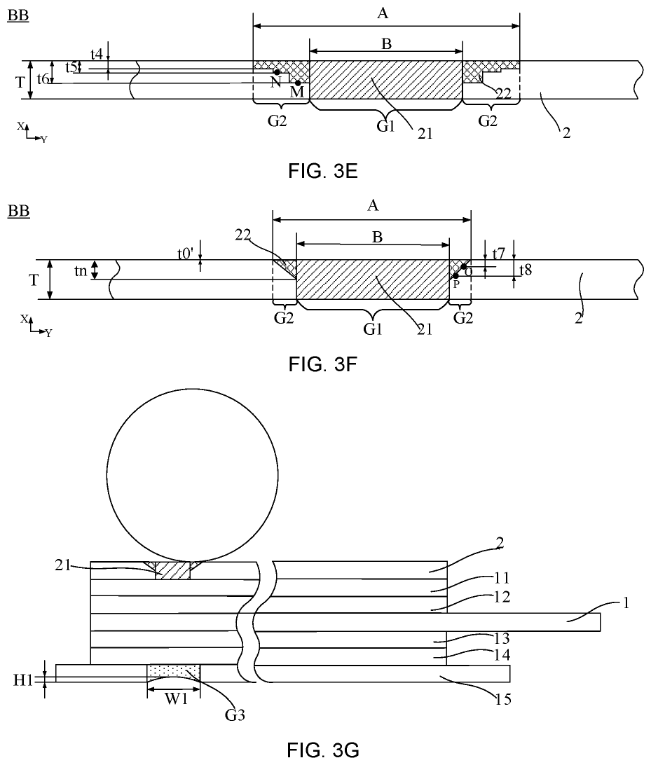

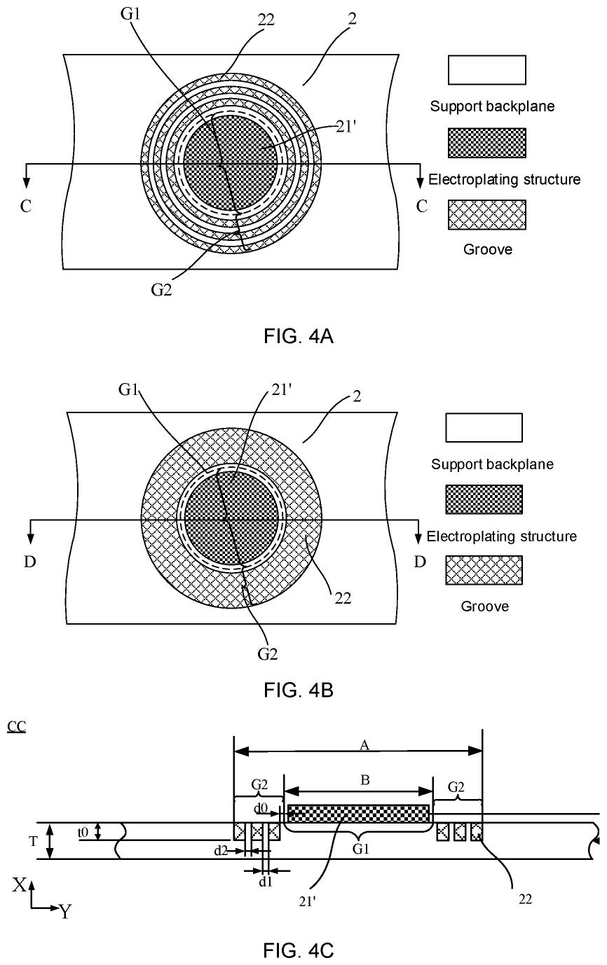

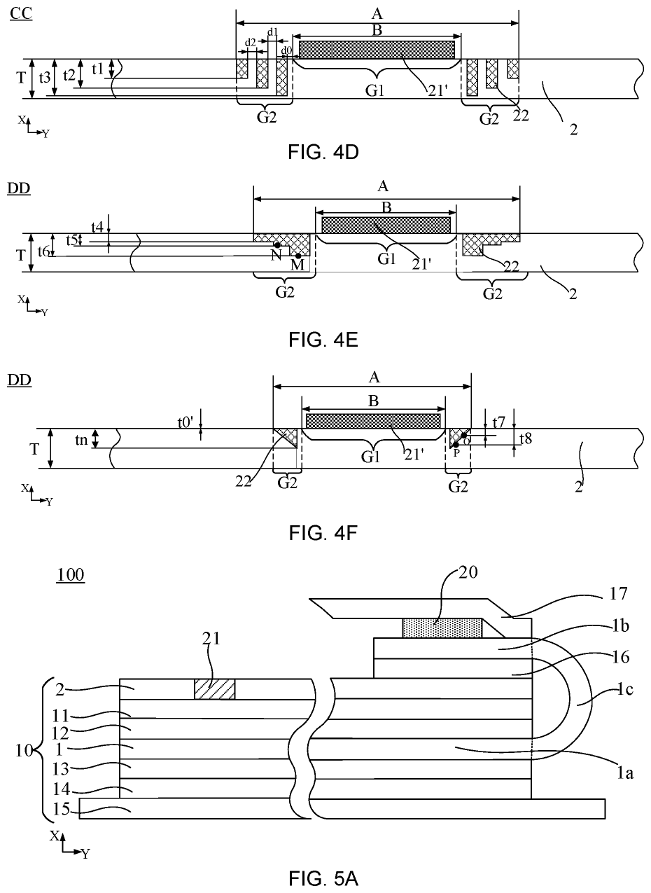

In the present disclosure, FIGS. 1A and 1B are diagrams each showing a stacked structure of the display module 10, and FIGS. 2A and 2B are schematic state diagrams of the display module 10 in which major film pressing marks are generated. In the stacked structure of the display module 10 shown in FIG. 1A or 1B, structures except a support backplane 2 are omitted in the structural diagrams shown in FIGS. 3C to 3F and 4C to 4F, so as to facilitate the description of the structure of the support backplane 2.

Some embodiments of the present disclosure provide the display module 10. As shown in FIGS. 1A and 1B, the display module 10 includes a display panel 1 and the support backplane 2 located on a side of the display panel 1 where a non-display surface S1 of the display panel 1 is located.

Referring to FIGS. 3A to 4F, the support backplane 2 has a first region G1 and a second region G2 disposed on a periphery of the first region G1. At least a portion of a portion, located in the second region G2, of the support backplane 2 is etched away to form groove(s) 22. It will be noted that a border of the first region G1 coincides with an inner border of the second region G2.

For example, in the planar structure of the support backplane 2 shown in FIG. 3A or 4A, in the portion of the support backplane 2 located in the second region G2, there are three portions are etched away to respectively form three grooves 22. In the planar structure of the support backplane 2 shown in FIG. 3B or 4B, the portion of the support backplane 2 located in the second region G2 is entirely etched away to form a groove 22. Here, the groove 22 is a downwardly depressed structure formed by etching inward from a surface of the support backplane 2. The groove 22 does not penetrate the support backplane 2, and the groove 22 is not filled with any material.

It will be noted that the first region G1 is a region of the support backplane 2 in which uneven structure(s) such as depression(s) or protrusion(s) exist. A through hole 21 or an electroplating structure 21′ is provided in the first region G1. For example, as shown in FIGS. 1A and 2A, the through hole 21 is disposed in the first region G1, and penetrates the support backplane 2. A border of the through hole 21 coincides with the inner border of the second region G2, i.e., coincides with the border of the first region G1. The entire region of the first region G1 is etched away to form the through hole 21, so that the first region G1 has a depression. Alternatively, as shown in FIGS. 1B and 2B, the first region G1 has the electroplating structure 21′ located on a side of the support backplane 2 away from the display panel 1. A border of the electroplating structure 21′ is spaced apart from the border of the first region G1. That is, the electroplating structure 21′ is located in the first region G1, and an area of an orthographic projection of the electroplating structure 21′ on the support backplane 2 is less than an area of the first region G1. The electroplating structure 21′ has a certain thickness relative to the surface of the support backplane 2, so that the first region G1 has a protrusion.

In some embodiments, as shown in FIGS. 2A and 2B, the display module 10 further includes other film layer structures. For example, the display module 10 further includes a cover plate 15 located on a side of the display panel 1 where a display surface S2 of the display panel 1 is located. The cover plate 15 has a film pressing mark region G3. The film pressing mark region G3 corresponds to the first region G1 of the support backplane 2 in a direction perpendicular to a plane where the support backplane 2 is located.

For example, as shown in FIGS. 2A and 2B, in the conventional support backplane 2, the support backplane 2 has the first region G1, and the first region G1 has the through hole 21 or the electroplating structure 21′, so that during an assembly of the display module, when the support backplane 2 and other film layers are bonded together through rolling pressing of a roller, stress concentration occurs at an edge of the first region G1. The direction indicated by the arrow is a direction of applying force, and deformation is easily generated at a rolling pressing position and at the edge in a process of applying force. Total energy of the bonding through the rolling pressing is decomposed into energy absorbed by the bottom structure portion and energy of the deformation by using the principle of conservation of energy. Thus, a phenomenon of depression or protrusion occurs, and a phenomenon of major film pressing marks occurs under strong light. For example, referring to FIG. 2A, the first region G1 of the support backplane 2 has the through hole 21, which results in deformation of the film pressing mark region G3 of the cover plate 15 at the bottom of the display module 10, so that the film pressing mark region G3 is depressed inward. For another example, referring to FIG. 2B, the first region G1 of the support backplane 2 has the electroplating structure 21′, which results in deformation of the film pressing mark region G3 of the cover plate 15 at the bottom of the display module 10 when the bonding is performed through the rolling pressing at the first region G1, so that the film pressing mark region G3 is protruded outward. Thus, a surface of the display module 10 is uneven, which affects a display effect and results in an obvious impact on vision.

In the support backplane 2 provided in some embodiments of the present disclosure, the second region G2 is disposed on the periphery of the first region G1, and the at least a portion of the portion of the support backplane 2 located in the second region G2 is etched away to form the groove(s) 22, so that the groove(s) 22 are used as a buffer structure to disperse stress acting on first region G1, thereby reducing the major film pressing marks caused by excessive stress concentration when the bonding is performed through the rolling pressing of the roller. Thus, a roughness of the film pressing mark region G3 of the cover plate 15 corresponding to the first region G1 is reduced, so that a flatness, a reliability and a yield of the display module 10 are improved, thereby improving the display effect.

In some embodiments, as shown in FIGS. 3A, 3C, 3D, 4A, 4C and 4D, a plurality of grooves 22 are disposed in the second region G2. The plurality of grooves 22 are loop-shaped, and the plurality of grooves 22 are sequentially spaced apart from inside to outside.

For example, as shown in FIGS. 3A and 4A, three grooves 22 are disposed in the second region G2. The three grooves 22 are loop-shaped, and the three grooves 22 are sequentially spaced apart from the inside to the outside. It will be noted that each of the plurality of grooves 22 is loop-shaped. Here, the term “loop-shaped” means that the groove 22 is in a shape of a closed figure in a plan view. For example, the groove 22 may be in a shape of a circular loop, or may be in a shape of a square loop (i.e., frame), but is not limited thereto. The three grooves 22 are sequentially spaced apart from the inside to the outside, which means that a position close to the first region G1 is the inside, a position away from the first region G1 is the outside, and the three grooves 22 extend toward the outside with the first region G1 as a center, and are sequentially spaced apart by certain distance(s).

It will be understood that, the spaced arrangement may ensure that during the pressing and bonding of the display module, the plurality of grooves 22 may have strengthened ability of absorbing impact energy, so as to better disperse the stress and have a better buffer effect, thereby further reducing the deformation of the display module 10.

In some embodiments, depths of the plurality of grooves 22 in a first direction X are equal. The first direction X is the direction perpendicular to the plane where the support backplane 2 is located.

For example, as shown in FIGS. 3C and 4C, the first direction X is the direction perpendicular to the plane where the support backplane 2 is located, i.e., a thickness direction of the support backplane 2. A thickness of the support backplane 2 is T, and the depths of the plurality of grooves 22 in the first direction X are t0. The depth, in the first direction X, of each groove 22, in a direction perpendicular to the first direction X from outside to inside, of the plurality of grooves 22 is equal, and is t0, and t0 is less than T (i.e., t0<T).

In some other embodiments, in a direction D from the inside to the outside with the first region G1 as the center (as shown in FIG. 3A), the depths of the plurality of grooves 22 in the first direction X are sequentially reduced.

For example, as shown in FIGS. 3D and 4D, in the direction from the inside to the outside with the first region G1 as the center, the depths of the plurality of grooves 22 in the first direction X are sequentially reduced. That is, a depth t3 of a first groove 22 is greater than a depth t2 of a second groove 22, and the depth t2 of the second groove 22 is greater than a depth t1 of a third groove 22.

In some embodiments, a spacing distance between two adjacent grooves 22 in the plurality of grooves 22 is equal. For example, the spacing distance two adjacent grooves 22 is 0.2 mm.

As shown in FIGS. 3C and 3D, in the direction from the inside to the outside with the first region G1 as the center, a spacing distance between two adjacent grooves 22 of a first group is d1, a spacing distance between two adjacent grooves 22 of a second group is d2, and d1 is equal to d2. It will be noted that the spacing distance here refers to a distance between closest edges of two adjacent grooves 22.

In some embodiments, a distance between a groove 22 closest to the first region G1 and the first region G1 is greater than or equal to the spacing distance between two adjacent grooves 22.

As shown in FIGS. 3C, 3D, 4C and 4D, the distance d0 between the groove 22 closest to the first region G1 and the first region G1 is greater than or equal to the spacing distance between two adjacent grooves 22, i.e., d0≥d1=d2.

In some embodiments, a ratio of the depth t of each of the plurality of grooves 22 to the thickness T of the support backplane is greater than or equal to 0.5 and less than 1.

Referring to FIGS. 3C and 4C, for example, the ratio of the depth t0 of each of the plurality of grooves 22 to the thickness T of the support backplane is 0.5. That is, the depth t of each of the plurality of grooves 22 is half of the thickness T of the support backplane, and the depth of each groove 22 is equal.

Referring to FIGS. 3D and 4D, for example, in the direction from the inside to the outside with the first region G1 as the center, a ratio of the depth t3 of the first groove 22 to the thickness T of the support backplane, a ratio of the depth t2 of the second groove 22 to the thickness T of the support backplane, and a ratio of the depth t1 of the third groove 22 to the thickness T of the support backplane are 0.9, 0.7 and 0.5, respectively. That is, the depths of the plurality of grooves 22 in the first direction X are sequentially reduced from the inside to the outside.

It will be noted that the ratio of the depth t of each of the plurality of grooves 22 to the thickness T of the support backplane is less than and not equal to 1, so that the second region G2 is prevented from being separated from the first region G1 when the second region G2 is etched to form the groove(s) 22, and the display effect is prevented from being affected due to a bad stress dispersion effect during the bonding through the rolling pressing of the roller.

For example, a half-etching depth represented by to in FIGS. 3C and 4C may be in a certain range, and t0 is greater than 0.5 T and less than 0.67 T; t1, t2 and t3 shown in FIGS. 3D and 4D are each less than T.

In some embodiments, as shown in FIGS. 3B, 3E, 3F, 4B, 4E and 4F, a single groove 22 is disposed in the second region G2. The groove 22 is loop-shaped, and the groove 22 and the first region G1 are not spaced apart. That is, an inner border of the groove 22 coincides with the inner border of the second region G2 (i.e., the border of the first region G1).

As shown in FIGS. 3E and 3F, the through hole 21 is disposed in the first region G1, and a border of the through hole 21 coincides with the inner border of the second region G2. The groove 22 and the first region G1 are not spaced apart. That is, the through hole 21 and the groove 22 are not spaced apart, and may be regarded as being connected as one, so as to form a large etching region. As shown in FIGS. 4E and 4F, the electroplating structure 21′ is disposed in the first region G1. The electroplating structure 21′ is located inside the first region G1, and the area of the orthographic projection of the electroplating structure 21′ on the support backplane 2 is less than the area of the first region G1. In this case, the groove 22 and the first region G1 are not spaced apart, which only means that the inner border of the groove 22 coincides with the border of the first region G1, and the electroplating structure 21′ is spaced apart from the groove 22.

It will be understood that the groove 22 and the first region G1 are not spaced apart, and in a case where the through hole 21 is disposed in the first region G1, the through hole 21 and the groove 22 may be regarded as being connected as one. That is, a spacing distance between the groove 22 and the first region G1 is 0, which is equivalent to increasing the area of the first region G1 to increase a stressed area perpendicular to the direction of applying force, so that the stress dispersion effect is further achieved. Thus, when the bonding is performed through the rolling pressing of the roller, the major film pressing marks caused by the excessive stress concentration are reduced, and the reliability and the yield of the display module 10 are improved.

In some embodiments, in a sectional view of the support backplane 2 taken along a straight line passing through the center of the first region G1, a depth, in the first direction X, of the groove 22 at a position away from the first region G1 is less than a depth, in the first direction X, of the groove 22 at a position close to the first region G1.

For example, as shown in FIGS. 3B and 4B, the single groove 22 is disposed in the second region G2, and the groove 22 is loop-shaped. It will be noted that the groove 22 is loop-shaped, which means that the groove 22 is in a shape of a closed figure in a plan view. For example, the groove 22 may be in a shape of a circular loop, or may be in a shape of a square loop (i.e., frame), but not limited thereto. The groove 22 is adjacent to the first region G1, and extends toward the outside with the first region G1 as the center.

Referring to FIGS. 3E and 4E, FIG. 3E is a sectional view of the support backplane 2 taken along the section line BB in FIG. 3B, and FIG. 4E is a sectional view of the support backplane 2 taken along the section line DD in FIG. 4B. Considering two positions of the groove 22, i.e., a position M and a position N, as an example, a depth t6, in the first direction X, of the groove 22 at the position M close to the first region G1 is greater than a depth t4, in the first direction X, of the groove 22 at the position N away from the first region G1.

Referring to FIGS. 3F and 4F, FIG. 3F is a sectional view of the support backplane 2 taken along the section line BB in FIG. 3B, and FIG. 4F is a sectional view of the support backplane 2 taken along the section line DD in FIG. 4B. Considering two positions of the groove 22, i.e., a position O and a position P, as an example, a depth t7, in the first direction X, of the groove 22 at the position O away from the first region G1 is less than a depth t8, in the first direction X, of the groove 22 at the position P close to the first region G1.

In some embodiments, as shown in FIGS. 3E, 3F, 4E and 4F, in the sectional view of the support backplane 2 taken along the straight line passing through the center of the first region G1, the groove 22 has a stepped or triangular shape.

In some embodiments, a ratio of a depth t of the groove 22 to the thickness T of the support backplane is less than or equal to 0.5.

Referring to FIGS. 3E and 4E, for example, the groove 22 has the stepped shape, and the groove 22 includes three steps. In the direction from the inside to the outside with the first region G1 as the center, depths of the three steps are sequentially reduced. Moreover, ratios of the depths t6, t5, t4 of the three steps of the groove 22 to the thickness T of the support backplane are 0.3, 0.2, and 0.1, respectively. That is, the depth of the groove 22 is sequentially reduced from the first region G1 from the inside to the outside in the direction perpendicular to the first direction X.

Referring to FIGS. 3F and 4F, for example, the groove 22 has the triangular shape. A maximum depth of the groove 22 is a depth tn at a position closest to the first region G1, and a minimum depth of the groove 22 is a depth t0′ at a position farthest from the first region G1. A ratio of the depth t0′, in the first direction X, of the groove 22 at the position farthest from the first region G1 to the thickness T of the support backplane is 0, i.e., t0′ is 0. A ratio of the depth tn, in the first direction X, of the groove 22 at the position closest to the first region G1 to the thickness T of the support backplane 2 is 0.5, and thus tn is greater than t0′ and less than T.

For example, referring to FIGS. 3E and 4E, the groove 22 with a half-etching depth has the stepped shape, and the depth of each step is in a certain range, i.e., t4 is less than or equal to 0.2 T (t4≤0.2 T), t4 is less than or equal to t5 that is less than or equal to 0.25 T (t4≤t5≤0.25 T), t4 is less than or equal to t6 that is less than or equal to 0.3 T (t4≤t6≤0.3 T). Referring to FIG. 4D, the maximum depth tn of the groove 22 is less than or equal to 0.5 T.

As shown in FIG. 3G, considering the groove 22 in the support backplane 2 shown in FIG. 3F or 4F as an example, the groove 22 is in contact with the first region G1, which is equivalent to increasing the area of the first region G1, and the section of the groove 22 has the triangular shape. The depth of the groove 22 is gradually decreased from the 18 inside to the outside with a smooth transition. The first region G1 is in contact with the groove 22, and when the support backplane 2 and the other film layers are bonded together through the rolling pressing of the roller, a certain degree of depression is formed in the film pressing mark region G3 of the cover plate 15. Comparing FIG. 3G with FIG. 2A, an area of the film pressing mark region G3 of the cover plate 15 in FIG. 3G is greater than an area of the film pressing mark region G3 of the cover plate 15 in FIG. 2A. That is, at the same position, a width W1 of the film pressing mark region G3 in FIG. 3G is greater than a width W of the film pressing mark region in FIG. 2A, and a depth H1 of the depression of the film pressing mark region G3 of the cover plate 15 in FIG. 3G is less than a depth H of the depression of the film pressing mark region G3 of the cover plate 15 in FIG. 2A. That is, the area of the first region G1 is increased, and accordingly, the area of the film pressing mark region G3 is increased, which is equivalent to sacrificing an area of a non-film pressing mark region to achieve less film pressing marks, so that the degree of depression is reduced, and the cover plate 15 has a planar surface, thereby improving the visual effect.

In some embodiments, the first region G1 is in a shape of a circle, and the groove 22 is in a shape of a circular loop.

Referring to FIGS. 3A and 4A, FIG. 3A is a diagram showing a planar structure of the support backplane in the display module 10 in the present disclosure, and FIG. 4A is a diagram showing another planar structure of the support backplane in the display module 10 in the present disclosure. The first region G1 is in the shape of the circle, each of the plurality of grooves 22 is in the shape of the circular loop, and the plurality of grooves 22 may be concentric rings. Referring to FIGS. 3B and 4B, the first region G1 is in the shape of the circle, and the groove 22 is in the shape of the circular loop. The above only gives examples of the shapes of the first region G1 and the groove(s) 22, and there may be other possible examples, which is not limited thereto.

In some embodiments, a ratio of a peripheral dimension A of the second region G2 to a peripheral dimension B of the first region G1 is 1.5.

It will be noted that, herein, the peripheral dimension A of the second region G2 refers to a dimension of an outer contour of an outermost groove 22 in the plurality of grooves 22 obtained by etching the entire second region G2, and the peripheral dimension B of the first region G1 refers to a dimension of an outer diameter of the first region G1. Moreover, when the ratio of the peripheral dimension A of the second region G2 to the peripheral dimension B of the first region G1 is calculated, in the sectional view taken along the section line passing through the center of the first region G1, referring to FIGS. 3C to 3F and 4C to 4F, a distance between two intersections of the border of the first region G1 and the section line is the peripheral size B of the first region G1, and a distance between two intersections of the outer contour of the outermost groove 22 and the section line is the peripheral dimension A of the second region G2, and A/B is 1.5.

For example, the ratio of the peripheral dimension A of the second region G2 to the peripheral dimension B of the first region G1 is set to be 1.5, which is more suitable for practical assembly. During assembly, not only the stress dispersion may be ensured to solve the problem of major film pressing marks, and but also the support and rigidity of the support backplane may be ensured to be not affected due to excessive etching.

The overall film layer structure of the display module 10 will be described below.

In some embodiments, as shown in FIGS. 1A and 1B, the display module 10 includes a first adhesive layer 11, a heat dissipation film 12, a polarizer 13, a second adhesive layer 14 and the cover plate 15.

The first adhesive layer 11 is disposed on a side of the support backplane 2 proximate to the display panel 1. The heat dissipation film 12 is disposed on a side of the first adhesive layer 11 proximate to the display panel 1. The polarizer 13 is disposed on the side of the display panel 1 where the display surface of the display panel 1 is located. The second adhesive layer 14 is disposed on a side of the polarizer 13 away from the display panel 1. The cover plate 15 is disposed on a side of the second adhesive layer 14 away from the display panel 1.

In some examples, the second adhesive layer 14 is an optically clear adhesive (OCA), and the polarizer 13 is adhered to the cover plate 15 by the OCA.

For example, the first adhesive layer 11 is composed of grid-like bonding adhesives arranged in an array, and may bond the support backplane 2 to the heat dissipation film 12 to absorb most of pressing and bonding energy during assembly, so that deformation transmitted to the heat dissipation film is reduced, thereby effectively reducing the phenomenon of major film pressing marks. The heat dissipation film 12 is made of, for example, polyimide through carbonization and graphitization, has a thickness of about 0.01 mm, and has a strong heat conduction performance. The polarizer 13 is made of an optical film material, and is used for controlling a polarization direction of a specific light beam. The cover plate 15 is made of an optical polyethylene terephthalate (PET) film or a transparent polyimide (PI) film, which is able to enhance the display effect.

In some examples, as shown in FIGS. 1A and 1B, the first region G1 of the support backplane 2 includes the through hole 21 or the electroplating structure 21′. A width b2 of the electroplating structure 21′ is slightly less than a width b1 of the through hole 21, and a depth a2 of the electroplating structure 21′ is less than a depth a1 of the through hole 21, as shown in FIGS. 1A and 1B, i.e., a2<a1, a1=T, and T is the thickness of the support backplane 2.

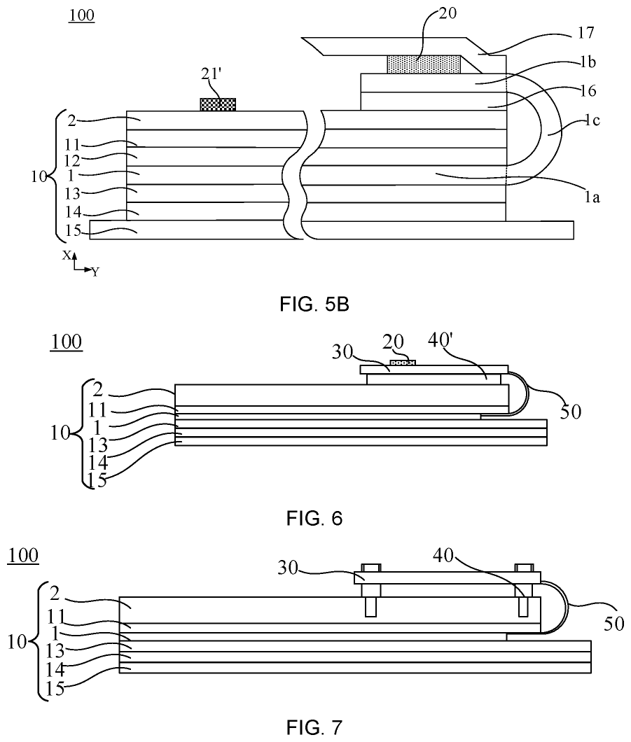

Some embodiments of the present disclosure further provide a display device 100. As shown in FIGS. 5A and 5B, the display device 100 includes the display module 10 and a driving chip 20. The driving chip 20 is electrically connected to the display panel 1 in the display module 10. The driving chip 20 is configured to provide a driving signal to the display module 10 to control the display module 10 for display.

In some embodiments, as shown in FIGS. 5A and 5B, the display panel 1 is a flexible display panel, and the display module 10 and the driving chip 20 are electrically connected by bending the flexible display panel. The display panel 1 includes a first region 1a, a second region 1b, and a bending region 1c located between the first region 1a and the second region 1b. The second region 1b of the display panel 1 is bent to the side of the support backplane 2 away from the display panel 1. An adhesive tape 16 is provided between the support backplane 2 and the second region 1b, and the support backplane 2 is fixedly connected to the second region 1b through the adhesive tape 16. The second region 1b of the display panel 1 is electrically connected to the driving chip 20.

For example, the first region 1a extends in a second direction Y with a length greater than that of the second region 1b, and the second direction Y is perpendicular to the first direction X. The adhesive tape 16 is disposed between the support backplane 2 and the second region 1b, and the adhesive tape 16 has a certain support effect, so that the bending region 1c of the display panel 1 may be prevented from being excessively bent and damaged.

As shown in FIGS. 5A and 5B, a chip encapsulation layer 17 is provided on the driving chip 20, and may block water vapor and oxygen to protect the driving chip 20.

In some other embodiments, as shown in FIGS. 6 and 7, the display device 100 further includes a printed circuit board 30 disposed on the side of the support backplane 2 away from the display panel 1. The printed circuit board 30 is electrically connected to the display panel 1 through a chip on film (COF) 50, and the driving chip 20 is disposed on the printed circuit board 30. The support backplane 2 is connected to the printed circuit board 30 through buffer connection member(s) 40. In the present embodiments, the display module 10 is electrically connected to the driving chip 20 through the printed circuit board 30 and the COF 50.

The buffer connection member 40 has a specific shape, so that when the display device 100 is subjected to vibration and impact, a risk of high deformation of the support backplane 2 and the printed circuit board 30 due to uneven stress is able to be avoided. A specific structure of the buffer connection member 40 will be described below.

For example, referring to FIG. 7, at least two fixing holes are provided in the printed circuit board 30 and the support backplane 2 for installation of the buffer connection member(s) 40. The fixing holes are each provided with internal threads.

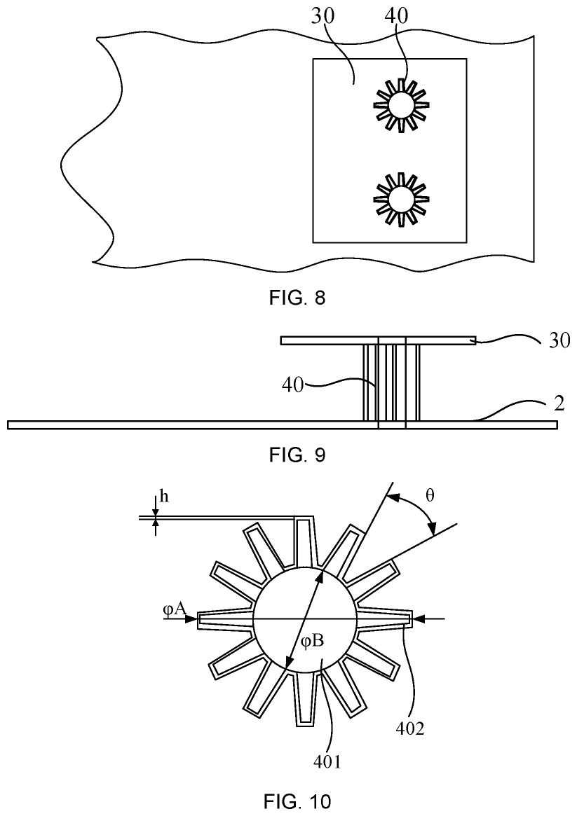

In some embodiments, as shown in FIGS. 8 to 11, the buffer connection member 40 includes a connection pillar 401 and a buffer bracket 402. The buffer bracket 402 is disposed on a periphery of the connection pillar 401, and the buffer bracket 402 has a hollow structure.

For example, the buffer connection member 40 is provided with threads on an outer wall of the connection pillar 401, and is installed on the support backplane 2 through threaded connection. A length of the connection pillar 401 is longer than that of the buffer bracket 402, so that the connection pillar 401 is able to be inserted into the fixing hole of the support backplane 2. Moreover, the threads on the outer wall of the connection pillar 401 are connected to the internal threads of the fixing hole, so that the buffer connection member 40 is fixedly connected to the support backplane 2. In addition, the printed circuit board 30 is also provided with the fixing hole, and a nut passes through the fixing hole to connect the printed circuit board 30 and the connection pillar 401, so as that the buffer connection member 40 is fixedly connected to the printed circuit board 30. For example, the number of the buffer connection member(s) 40 is two.

For example, the buffer bracket 402 is arranged to have the hollow structure, which may, on one hand, save material, and on another hand, may disperse a shearing force in the second direction Y, so as to avoid the risk of high deformation of the printed circuit board 30 and the display module 10 due to the force transmission effect under high temperature, high frequency vibration and impact.

In some embodiments, as shown in FIG. 10, an orthographic projection of the buffer connection member 40 on the support backplane 2 is in a shape of a gear, and an angle θ between two adjacent teeth of the gear is greater than 15°. A wall thickness h of each tooth is greater than or equal to 0.02 mm.

For example, the orthographic projection of the buffer connection member 40 on the support backplane 2 is in the shape of the gear. That is, the buffer bracket 402 is gear-shaped, and may uniformly disperse the stress concentration. The arrangement of the wall thickness h of each tooth on the gear may increase a stressed area of the support backplane 2 and the printed circuit board 30 in the first direction X, so as to avoid wear due to a fact that two connection surfaces of the support backplane 2 and the printed circuit board 30 are subjected to a radial force in the first direction X. A length of the buffer bracket 402 is equal to a distance between the support backplane 2 and the printed circuit board 30, so as to avoid shaking under vibration impact.

In some embodiments, as shown in FIG. 10, a difference between a tip diameter φA of the gear and a root diameter φB of the gear is greater than or equal to 0.2 mm, and the root diameter φB of the gear is greater than or equal to 3 mm.

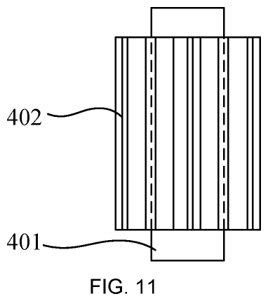

In some embodiments, as shown in FIG. 11, the buffer connection member 40 is made of metal. The connection pillar 401 is a metal pillar, and the buffer bracket 402 is formed by folding a reinforcing steel plate.

For example, the connection pillar 401 and the buffer bracket 402 are connected by welding. The connection pillar 401 has a hollow cylindrical structure.

In yet other embodiments, referring to FIG. 6, a bonding adhesive 40′ is provided between the printed circuit board 30 and the support backplane 2, and the support backplane 2 is connected to the printed circuit board 30 through the bonding adhesive 40′.

Beneficial effects that can be achieved by the display device 100 in the above embodiments of the present disclosure are the same as the beneficial effects that can be achieved by the above display module 10, and will not be repeated here. Moreover, as the second embodiment of the display device 100 provided in the present disclosure, the buffer connection member(s) 40 with the shape of the gear are arranged, so that the printed circuit board 30 is connected to the support backplane 2, so that the connection performance is more stable, and the shock resistance is strong, thereby improving the strength of the display device 100.

The display device 100 may be any device that displays text or images whether moving (e.g., videos) or stationary (e.g., still images). More specifically, it is anticipated that the embodiments may be implemented in, or associated with, a variety of electronic devices. The variety of electronic devices are, for example (but not limit to), mobile phones, wireless devices, personal digital assistants (PDAs), hand-held or portable computers, global positioning system (GPS) receivers/navigators, cameras, MP4 video players, camcorders, game consoles, watches, clocks, calculators, television monitors, flat panel displays, computer monitors, auto displays (e.g., odometer displays), navigators, cockpit controllers and/or displays, camera view displays (e.g., rear-view camera displays in vehicles), electronic photos, electronic billboards or signs, projectors, architectural structures, packaging and aesthetic structures (e.g., displays for displaying an image of a piece of jewelry).

In the display module 10 described in some embodiments of the present disclosure, the buffer structure is disposed on the periphery of the through hole, and a portion of the periphery of the through hole is etched, so that the deformation caused by the stress concentration during the rolling pressing of the roller may be reduced, and the major film pressing marks in the prior art are able to be reduced, thereby providing more perfect visual effect for consumers.

For example, the at least a portion of the portion of the support backplane 2 located in the second region G2 may be etched away to form the groove(s) 22, so as to increase the stressed area and the stress dispersion of the support backplane 2 during the rolling pressing of the roller, so that the deformation is reduced by increasing the width of the film pressing mark region G3, thereby further reducing the film pressing marks and improving the visual effect of the display device 100.

The foregoing descriptions are merely specific implementation manners of the present disclosure, but the protection scope of the present disclosure is not limited thereto. Changes or replacements that any person skilled in the art could conceive of within the technical scope of the present disclosure shall all be included in the protection scope of the present disclosure. Therefore, the protection scope of the present disclosure shall be subject to the protection scope of the claims.

1. A display module, comprising:
a display panel; and
a support backplane disposed on a side of the display panel where a non-display surface of the display panel is located; wherein the support backplane has a first region and a second region disposed on a periphery of the first region; at least a portion of a portion, located in the second region, of the support backplane is etched away to form at least one groove.

2. The display module according to claim 1, wherein
the at least one groove includes a plurality of grooves;
the plurality of grooves are loop-shaped, and are sequentially spaced apart from inside to outside.

3. The display module according to claim 2, wherein
depths of the plurality of grooves in a first direction are equal, and the first direction is a direction perpendicular to a plane where the support backplane is located; or
in a direction from the inside to the outside with the first region as a center, the depths of the plurality of grooves in the first direction are sequentially reduced.

4. The display module according to claim 2, wherein a spacing distance between two adjacent grooves in the plurality of grooves is equal, and a distance between a groove closest to the first region and the first region is greater than or equal to the spacing distance between the two adjacent grooves.

5. The display module according to claim 2, wherein a ratio of a depth, in a first direction, of each of the plurality of grooves to a thickness, in the first direction, of the support backplane is greater than or equal to 0.5 and is less than 1; the first direction is a direction perpendicular to a plane where the support backplane is located.

6. The display module according to claim 1, wherein the at least one groove includes a single groove; the groove is loop-shaped, and the groove and the first region are non-spaced apart.

7. The display module according to claim 6, wherein in a sectional view of the support backplane taken along a straight line passing through a center of the first region, a depth, in a first direction, of the groove at a position away from the first region is less than a depth, in the first direction, of the groove at a position close to the first region; the first direction is a direction perpendicular to a plane where the support backplane is located.

8. The display module according to claim 7, wherein in the sectional view, the groove has a stepped or triangular shape.

9. The display module according to claim 6, wherein a ratio of a depth of the groove in a first direction to a thickness of the support backplane in the first direction is equal to or less than 0.5; the first direction is a direction perpendicular to a plane where the support backplane is located.

10. The display module according to claim 1, wherein the first region is in a shape of a circle, and a groove in the at least one groove is in a shape of a circular loop.

11. The display module according to claim 1, wherein a ratio of a peripheral dimension of the second region to a peripheral dimension of the first region is 1.5.

12. The display module according to claim 1, wherein a through hole is disposed in the first region, and a border of the through hole coincides with an inner border of the second region; or
an electroplating structure is disposed in the first region, and is located on a side of the support backplane away from the display panel; a border of the electroplating structure is spaced apart from a border of the first region.

13. The display module according to claim 1, wherein the display module further comprises:
a first adhesive layer disposed on a side of the support backplane proximate to the display panel;
a heat dissipation film disposed on a side of the first adhesive layer proximate to the display panel;
a polarizer disposed on a side of the display panel where a display surface of the display panel is located;
a second adhesive layer disposed on a side of the polarizer away from the display panel; and
a cover plate disposed on a side of the second adhesive layer away from the display panel.

14. A display device, comprising:
the display module according to claim 1; and
a driving chip electrically connected to the display panel in the display module.

15. The display device according to claim 14, wherein the display panel includes a first region, a second region and a bending region located between the first region and the second region; the second region of the display panel is bent to a side of the support backplane away from the display panel; an adhesive tape is disposed between the support backplane and the second region of the display panel, and the support backplane is fixedly connected to the second region of the display panel through the adhesive tape; the second region of the display panel is electrically connected to the driving chip.

16. The display device according to claim 14, further comprising a printed circuit board disposed on a side of the support backplane away from the display panel; wherein the printed circuit board is electrically connected to the display panel through a chip on film, and the driving chip is disposed on the printed circuit board; the support backplane is connected to the printed circuit board through a buffer connection member.

17. The display device according to claim 16, wherein the buffer connection member includes a connection pillar and a buffer bracket disposed on a periphery of the connection pillar, and the buffer bracket has a hollow structure.

18. The display device according to claim 17, wherein an orthographic projection of the buffer connection member on the support backplane is in a shape of a gear;
an angle between two adjacent teeth of the gear is greater than 15°, and a wall thickness of each tooth is greater than or equal to 0.02 mm.

19. The display device according to claim 18, wherein a difference between a tip diameter of the gear and a root diameter of the gear is greater than or equal to 0.2 mm, and the root diameter of the gear is greater than or equal to 3 mm.

20. The display device according to claim 17, wherein the buffer connection member is made of metal; the connection pillar is a metal pillar, and the buffer bracket is formed by folding a reinforcing steel plate.
